(19) United States
(12) Patent Application Publication
(10) Pub. No.: US 2026/0125315 A1
(43) Pub. Date: May 7, 2026

(54) MICROELECTRONIC ARTICLES THAT INCLUDE GLASS-BASED SUBSTRATES AND POLYMER LAYERS

(71) Applicant: CORNING INCORPORATED, CORNING, NY (US)

(72) Inventors: Mandakini Kanungo, Ithaca, NY (US); Chukwudi Azubuike Okoro, Painted Post, NY (US); Stanislav Sikulskyi, Corning, NY (US); Rajesh Vaddi, Horseheads, NY (US)

(21) Appl. No.: 19/368,288

(22) Filed: Oct. 24, 2025

Related U.S. Application Data
(60) Provisional application No. 63/716,350, filed on Nov. 5, 2024.

(51) Int. Cl. C03C 17/38; C03C 17/36; H01L 23/15; H01L 23/498

(52) U.S. Cl. CPC C03C 17/38; C03C 17/3668; H10W 70/635; H10W 70/69; H10W 70/692; C03C 2217/253; C03C 2217/70

(57) ABSTRACT

A microelectronic article includes a glass-based substrate having a first surface and a second surface, a first polymer layer disposed on the first surface, a second polymer layer disposed on the second surface, at least one redistribution layer disposed on the first polymer layer, the second polymer layer, or both, and a metallized through glass via extending from the first surface to the second surface. The first polymer layer and the second polymer layer include pores and have a porosity of from 5% to 70% and a Young's modulus of greater than 1 GPa. The at least one redistribution layer includes a metal material and a dielectric material.

This application claims the benefit of priority under 35 U.S.C. § 119 of U.S. Provisional Application Ser. No. 63/716,350 filed on Nov. 5, 2024, the content of which is relied upon and incorporated herein by reference in its entirety.

### TECHNICAL FIELD

Embodiments of the present disclosure generally relate to microelectronic articles and, more specifically, to microelectronic articles including glass-based substrates and polymer layers.

### BACKGROUND

Glass-based substrates are widely used in microelectronic articles due to attributes such as low dielectric constant, high rigidity, and panel size capability. Conventionally, using glass-based substrates in microelectronics requires an overlay of multiple layers of metal and dielectric materials, often referred to as redistribution layers or RDLs. The buildup of the redistribution layers and the different coefficients of thermal expansion and/or Young's modulus between the glass-based substrate and the redistribution layers may induce stresses that are transferred to the glass-based substrate, resulting in lateral fractures. As such, microelectronic articles that minimize glass fractures are desired by the industry.

### SUMMARY

Accordingly, described herein are microelectronic articles that include a glass-based substrate comprising a first surface and a second surface, a first polymer layer disposed on the first surface, a second polymer layer disposed on the second surface, and at least one redistribution layer disposed on the first polymer layer, the second polymer layer, or both. It has presently been discovered that microelectronic articles with glass-based substrates that utilize polymer layers described herein have reduced stress transfer to the glass-based substrate than conventional microelectronic articles with glass-based substrates and that do not include such polymer layers. The polymer layers may comprise pores, additives, or the polymer layers may comprise certain properties each of which allow the polymer layers to serve as an adhesive-buffer layer between the glass-based substrate and the one or more redistribution layers.

According to embodiments described herein, a microelectronic article may comprise a glass-based substrate comprising a first surface and a second surface, a first polymer layer disposed on the first surface, a second polymer layer disposed on the second surface, at least one redistribution layer disposed on the first polymer layer, the second polymer layer, or both, and a metallized through glass via extending from the first surface to the second surface. The first polymer layer and the second polymer layer may comprise pores and have a porosity of from 5% to 70% and a Young's modulus of greater than 1 GPa. The at least one redistribution layer may comprise a metal material and a dielectric material.

According to additional embodiments described herein, a microelectronic article may comprise a glass-based substrate comprising a first surface and a second surface, at least one redistribution layer disposed on the first surface, the second surface, or both, and a metallized through glass via extending from the first surface to the second surface. The at least one redistribution layer may comprise a dielectric material and a metal material. The dielectric material may comprise pores and have a porosity of from 5% to 70% and a Young's modulus of greater than 1 GPa.

According to additional embodiments described herein, a microelectronic article may comprise a glass-based substrate comprising a first surface and a second surface, a first polymer layer disposed on the first surface, a second polymer layer disposed on the second surface, at least one redistribution layer disposed on the first polymer layer, the second polymer layer, or both, and a metallized through glass via extending from the first surface to the second surface. The first polymer layer and the second polymer layer may have a Young's modulus of from 1 GPa to 10 GPa. The at least one redistribution layer may comprise a metal material and a dielectric material.

According to additional embodiments described herein, a microelectronic article pre-structure may comprise a glass-based substrate comprising a first surface and a second surface and at least one polymer layer disposed on the first surface, the second surface, or both. The at least one polymer layer may comprise pores and have a porosity of from 5% to 70% and a Young's modulus of from 1 GPa to 10 GPa.

These and other embodiments are described in more detail in the Detailed Description. It is to be understood that both the foregoing general description and the following detailed description present embodiments of the subject technology, and are intended to provide an overview or framework for understanding the nature and character of the described technology as it is claimed. The accompanying drawings are included to provide a further understanding of the presently disclosed technology and are incorporated into and constitute a part of this specification. The drawings illustrate various embodiments and, together with the description, serve to explain the principles and operations of the presently described technology. Additionally, the drawings and descriptions are meant to be merely illustrative, and are not intended to limit the scope of the claims in any manner.

### BRIEF DESCRIPTION OF THE DRAWINGS

The following detailed description of specific embodiments of the present disclosure can be best understood when read in conjunction with the following drawings, where the structure is indicated with like reference numerals and in which:

FIG. 1 schematically depicts a cross-sectional side view of a conventional microelectronic article having a fracture in the glass-based substrate;

FIG. 2 schematically depicts a cross-sectional side view of a microelectronic article, according to one or more embodiments described in this disclosure;

FIG. 3 schematically depicts a cross-sectional side view of a microelectronic article, according to one or more embodiments described in this disclosure;

FIG. 4 schematically depicts a cross-sectional side view of a microelectronic article, according to one or more embodiments described in this disclosure;

FIG. 5A depicts a 2D axisymmetric model of a microelectronic article, according to one or more embodiments described in this disclosure;

FIG. 5B schematically depicts a section of FIG. 5A, according to one or more embodiments described in this disclosure;

FIG. 5C is a magnified illustration of a portion of FIG. 5B, according to one or more embodiments described in this disclosure;

FIG. 6A is a schematic illustration of a cross-sectional side view of Comparative Example A;

FIG. 6B is a schematic illustration of a cross-sectional side view of Example 1, according to one or more embodiments described in this disclosure;

FIG. 6C is a schematic illustration of a cross-sectional side view of Example 2, according to one or more embodiments described in this disclosure;

FIG. 7A is a graph plotting the applied temperature for each layer of the microelectronic article of Comparative Example A;

FIG. 7B is a graph plotting the applied temperature for each layer of the microelectronic article of Examples 1 and 2, according to one or more embodiments described in this disclosure; and

FIG. 8 is a graph plotting the stress vs. location in the glass-based substrate of a microelectronic article for Comparative Example A and one or more embodiments described herein.

Reference will now be made in greater detail to various embodiments, some embodiments of which are illustrated in the accompanying drawings. Whenever possible, the same reference numerals will be used throughout the drawings to refer to the same or similar parts.

### DETAILED DESCRIPTION

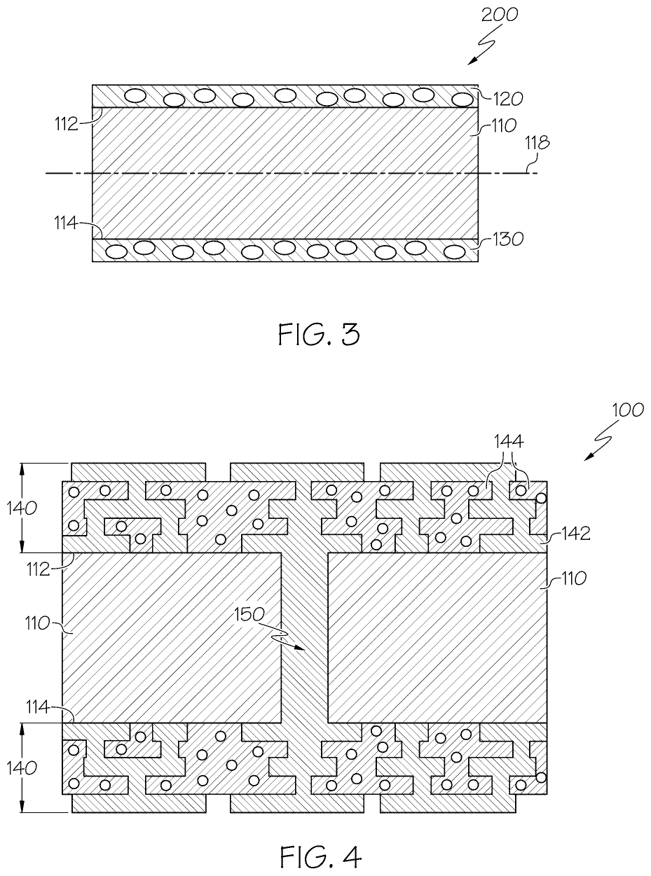

Embodiments of the present disclosure relate to microelectronic articles including glass-based substrates and polymer layers. The embodiments of FIGS. 2, 3, 4, 5A-5C, and 6A-6C are similar or identical in many ways, respectively, but may include differences as described herein. Descriptions of the embodiments of FIGS. 2, 3, 4, 5A-5C, and 6A-6C may generally apply to the embodiments of the other figures, as would be understood by those skilled in the art. For example, concepts disclosed herein applicable to FIG. 2 may be equally applicable to FIG. 3 and vice versa, even if not explicitly stated as such herein.

As used herein, the term “glass-based substrate” refers to a substrate that comprises amorphous glass or glass-ceramics, and does not include fiberglass. The term “glass-ceramic” may refer to solids prepared by controlled crystallization of a precursor glass and have one or more crystalline phases and a residual amorphous glass phase.

As used herein, the term “dispose” refers to any coating, depositing, and/or forming of a material onto a surface using any known method in the art. The disposed material may constitute a layer, as described herein. The phrase “disposed on” may include the instance of forming or depositing a material onto a surface such that the material is in direct contact with the surface and also may include the instance where the material is formed or deposited on a surface, with one or more intervening materials between the disposed material and the surface. The intervening materials may constitute a layer, as described herein.

As used herein, a “layer” refers to a sheet of a material that has generally even thickness covering a surface. A “redistribution layer” may refer to the layer comprising dielectric and metal materials that make up an integrated circuit of a microelectronic article, as known by those skilled in the art. In some embodiments, a redistribution layer may be “integrated” such that the dielectric material and the metal material present in the redistribution layer are joined in an intertwined manner, such as, for example, in FIG. 2. In such embodiments, the dielectric material may be etched, lasered, or otherwise modified to create gaps that are filled with metal material, and vice versa. This process, described further herein, may result in an “integrated” redistribution layer.

As used herein, the Young's modulus values were obtained from literature to be used for the examples described herein. Specifically, the Young's modulus values herein were obtained from Ledbetter et al. “Properties of Metals and Alloys II. Copper”, J. Phys. Chem. Ref. Data 3, 897-935 (1974), Okoro et al. “Novel Cu—Cu Bonding Technique: The Insertion Bonding Approach”, IEEE Transactions on Components, Packaging and Manufacturing Technology 1 (12), 1885-1894 (2011), and Narahashi “Low Df Build-up Material for High Frequency Signal Transmission of Substrates,” The 63rd IEEE Electronic Components and Technology Conference (ECTC), Las Vegas, May 28-31, 2013, which are incorporated herein by reference in their entireties. Experimentally, the Young's modulus values are determined using resonant ultrasound spectroscopy, following the methodology detailed in Maynard, “Resonant Ultrasound Spectroscopy”, Physics Today, Vol. 49 (1). 26-31, 1996. “Young's modulus” may also be referred to as “elastic modulus” as used in this disclosure.

As used herein, the porosity values were measured by the Brunauer-Emmett-Teller (BET) method. The BET method may be used to measure the surface area of solids and/or porous materials, which indicates how the area of a material's surface affects its interaction with the environment. The BET method is a gas adsorption method that measures the surface area and porosity of solids. It involves exposing a solid to a gas, usually nitrogen, at cryogenic temperatures. The technique then measures the amount of gas adsorbed and the relative pressure. The BET method can measure the total specific surface area, pore size, and pore volume distribution of a material. It can be used on non-porous materials and porous materials with a range of pore size from microporous to mesoporous to macroporous.

As used herein, the stress values were evaluated by finite element modeling (ANSYS Mechanical 2023R1), as described in the examples herein.

As used herein, the pore size values were measured by scanning electron microscopy (SEM), which is a technique that uses a focused beam of electrons to scan a sample's surface and create images. SEM images are collected systematically over an area and the images are segmented into porous and non-porous sections. The total area of pores is determined and pore size is calculated by averaging the number of pores to the total area of pores. SEM can be used to measure the pore size and shape and the pore distributions in the sample.

As used herein, the coefficient of thermal expansion (CTE) values were measured by thermomechanical analysis (TMA) which is a technique used to measure how a material deforms over time or temperature while under a constant force. TMA was performed herein following ASTM E831-24.

As used herein, the decomposition temperature values were measured by thermogravimetric analysis (TGA) which is a method of thermal analysis in which the mass of a sample is measured over time as the temperature changes. TGA was performed herein following ASTM E1131.

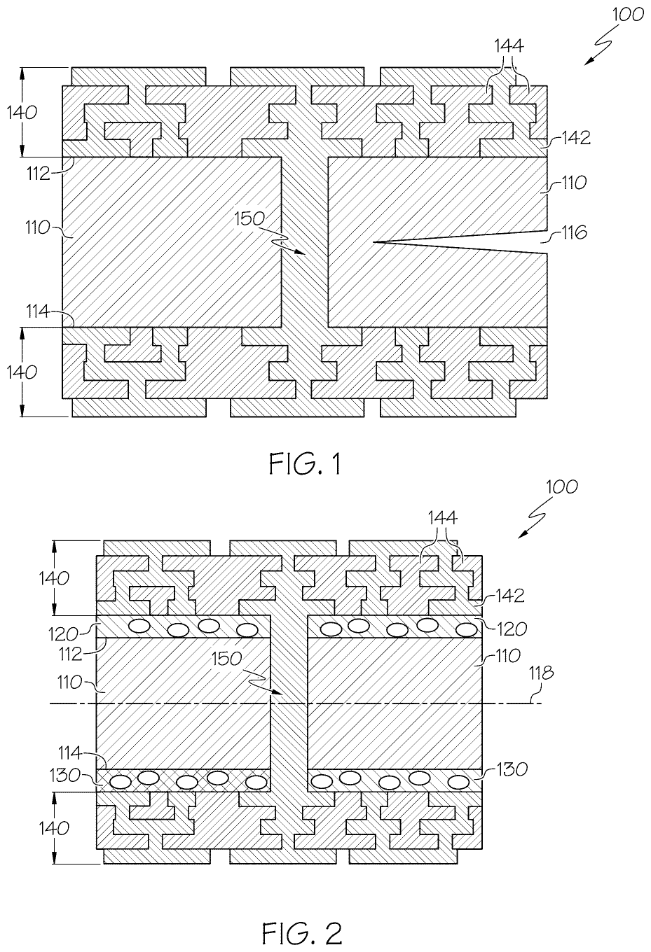

Now referring to FIG. 1, a cross-sectional side view of a microelectronic article 100 is depicted. FIG. 1 depicts a conventional microelectronic article 100 used in the industry. The microelectronic article 100 comprises a glass-based substrate 110 comprising a first surface 112 and a second surface 114. At least one redistribution layer (RDL) 140 is disposed on the first surface 112 and the second surface 114. The RDLs 140 comprise a metal material 142 and a dielectric material 144. The metal material 142 and the dielectric material 144 are integrated in the RDLs 140. The microelectronic article 100 further comprises a through glass via 150. The through glass via 150 may be an aperture that extends from the first surface 112 to the second surface 114. The through glass via 150 may comprise the metal material 142 such that the metal material 142 serves as an electrical interconnect through the microelectronic article 100. In some embodiments, the metal material 142 may be disposed in the through glass via 150 prior to formation of the redistribution layers 140. The formation process of the microelectronic article 100 is described further herein. Without being bound by any particular theory, the redistribution layers 140 may cause stress buildup in the glass-based substrate 110, especially in the first surface 112 and the second surface 114. The stresses may be caused by property mismatches of the different materials in the RDL 140, such as a mismatch between the coefficients of thermal expansion and/or Young's modulus of the metal material 142 and the dielectric material 144. These stresses may build up in the RDLs 140 and may be transferred to the glass-based substrate 110. Since the glass-based substrate 110 is unable to deform due to the rigidity of the RDLs 140, the stresses may result in lateral fractures 116 in the glass-based substrate 110. Accordingly, there is a need to minimize the likelihood of these fractures when utilizing glass-based substrates in microelectronic articles.

Now referring to FIG. 2, a microelectronic article 100 according to one or more embodiments described herein is depicted. Embodiments of the microelectronic article 100 depicted in FIG. 2 comprise a glass-based substrate 110 comprising a first surface 112 and a second surface 114, a first polymer layer 120 disposed on the first surface 112 of the glass-based substrate 110, a second polymer layer 130 disposed on the second surface 114 of the glass-based substrate 110, and a RDL 140 disposed on the first polymer layer 120 and a RDL 140 disposed on the second polymer layer 130. In one or more embodiments, a RDL 140 is disposed only on the first polymer layer 120, and in other embodiments a RDL 140 is disposed only on the second polymer layer 130.

In one or more embodiments, the glass-based substrate 110 may have a coefficient of thermal expansion (CTE) that is from 0.5×10⁻⁶/° C. to 13×10⁻⁶/° C. over a temperature range of −100° C. to 450° C. In some embodiments, the glass-based substrate 110 may have a CTE that is from 0.5×10⁻⁶/° C. to 1×10⁻⁶/° C., from 0.5×10⁻⁶/° C. to 12×10⁻⁶/° C., from 0.5×10⁻⁶/° C. to 10×10⁻⁶/° C., from 0.5×10⁻⁶/° C. to 8×10⁻⁶/° C., from 0.5×10⁻⁶/° C. to 6×10⁶/° C., from 0.5×10⁻⁶/° C. to 4×10⁻⁶/° C., from 0.5×10⁻⁶/° C. to 2×10⁻⁶/° C., from 1×10⁻⁶/° C. to 13×10⁻⁶/° C., from 2×10⁻⁶/° C. to 13×10⁻⁶/° C., from 4×10⁻⁶/° C. to 13×10⁻⁶/° C., from 6×10⁻⁶/° C. to 13×10⁻⁶/° C., from 8×10⁻⁶/° C. to 13×10⁻⁶/° C., from 10×10⁻⁶/° C. to 13×10⁻⁶/° C., from 12×10⁻⁶/° C. to 13×10⁻⁶/° C., or any combinations of these ranges.

In one or more embodiments, the glass-based substrate 110 may have a Young's modulus that is from 50 GPa to 200 GPa. For example, in some embodiments, the glass-based substrate 110 may have a Young's modulus that is from 50 GPa to 200 GPa, from 75 GPa to 200 GPa, from 100 GPa to 200 GPa, from 125 GPa to 200 GPa, from 50 GPa to 175 GPa, from 50 GPa to 150 GPa, from 50 GPa to 125 GPa, from 50 GPa to 100 GPa, from 50 GPa to 75 GPa, from 75 GPa to 175 GPa, from 100 GPa to 150 GPa, or any combinations of these ranges.

In one or more embodiments, the glass-based substrate 110 may have a thickness that is from 100 μm to 1000 μm. For example, in some embodiments, the glass-based substrate 110 may have a thickness that is from 150 μm to 1000 μm, from 200 μm to 1000 μm, from 250 μm to 1000 μm, from 300 μm to 1000 μm, from 350 μm to 1000 μm, from 400 μm to 1000 μm, from 450 μm to 1000 μm, from 500 μm to 1000 μm, from 550 μm to 1000 μm, from 600 μm to 1000 μm, from 650 μm to 1000 μm, from 700 μm to 1000 μm, from 750 μm to 1000 μm, from 800 μm to 1000 μm, from 850 μm to 1000 μm, from 900 μm to 1000 μm, from 950 μm to 1000 μm, from 100 μm to 950 μm, from 100 μm to 900 μm, from 100 μm to 850 μm, from 100 μm to 800 μm, from 100 μm to 750 μm, from 100 μm to 700 μm, from 100 μm to 650 μm, from 100 μm to 600 μm, from 100 μm to 550 μm, from 100 μm to 500 μm, from 100 μm to 450 μm, from 100 μm to 400 μm, from 100 μm to 350 μm, from 100 μm to 300 μm, from 100 μm to 250 μm, from 150 μm to 950 μm, from 200 μm to 900 μm, from 250 μm to 850 μm, from 300 μm to 800 μm, from 350 μm to 750 μm, from 400 μm to 700 μm, or any combinations of these ranges. The thickness of the glass-based substrate 110 refers to the distance extending from the first surface 112 to the second surface 114. As described herein, thickness of the glass-based substrate 110 may be measured by using a micrometer gauge.

Still referring to FIG. 2, and as stated herein, the microelectronic article 100 comprises a first polymer layer 120 disposed on the first surface 112 of the glass-based substrate 110 and a second polymer layer 130 disposed on a second surface 114 of the glass-based substrate 110. In some embodiments, the first polymer layer 120 may be in direct contact with the first surface 112 of the glass-based substrate 110, such that the first polymer layer 120 is sandwiched between one RDL 140 and the first surface 112 of the glass-based substrate 110. In some embodiments, the second polymer layer 130 may be in direct contact with the second surface 114 of the glass-based substrate 110, such that the second polymer layer 130 is sandwiched between another RDL 140 and the second surface 114 of the glass-based substrate 110. Without being bound by any particular theory, the first polymer layer 120 and the second polymer layer 130, when in contact with the glass-based substrate 110, may act as stress buffer layers between the glass-based substrate 110 and the RDLs 140, minimizing the likelihood of fractures in the glass-based substrate 110 As a result, a smaller thermal load is transferred from the RDLs 140 to the surfaces 112, 114 of the glass-based substrate 110.

In one or more embodiments, the first polymer layer 120 and the second polymer layer 130 may have a thickness that is from 1 μm to 30 μm. For example, in some embodiments, the first polymer layer 120 and the second polymer layer 130 may have a thickness that is from 2 μm to 30 μm, from 5 μm to 30 μm, from 10 μm to 30 μm, from 15 μm to 30 μm, from 20 μm to 30 μm, from 25 μm to 30 μm, from 1 μm to 25 μm, from 1 μm to 20 μm, from 1 μm to 15 μm, from 1 μm to 10 μm, from 1 μm to 5 μm, from 5 μm to 25 μm, from 10 μm to 20 μm, or any combinations of these ranges. Referring to FIG. 2, a non-limiting example of the thickness of the first polymer layer 120 is the distance from the first surface 112 to the RDL 140. As described herein, the thickness of the first polymer layer 120 and the second polymer layer 130 may be measured by scanning electron microscopy (SEM) cross sectional analysis.

In some embodiments, the first polymer layer 120 and the second polymer layer 130 may comprise pores. Without being limited by theory, it is believed that pores in the first polymer layer 120 and the second polymer layer 130 may limit the stresses transferred to the glass-based substrate 110 from the at least one RDL 140 by acting as stress sinks, such as by allowing the pores to stretch and contract as stresses are applied to the first polymer layer 120 and/or the second polymer layer 130. Additionally, it is believed that the presence of pores allows the polymer layers 120, 130 to undergo larger deformation when the RDLs 140 thermally deform. The first polymer layer 120 and the second polymer layer 130 may also serve as an adhesive layer, such that the polymer layers have good adhesion to glass, glass-ceramics, metal materials, and dielectric materials. For example, the polymer layers 120, 130 may have an adhesion strength greater than or equal to 3 N/mm², as measured by ASTM D4541-22. As such, the first polymer layer 120 and the second polymer layer 130 may be porous polymer layers that dually serve as a stress buffer layer and as an adhesive layer between the glass-based substrate 110 and the RDLs 140.

In some embodiments, the first polymer layer 120 and the second polymer layer 130 may have a porosity that is from 5% to 70%. For example, in some embodiments, the first polymer layer 120 and the second polymer layer 130 may have a porosity that is from 5% to 65%, from 5% to 60%, from 5% to 55%, from 5% to 50%, from 5% to 45%, from 5% to 40%, from 5% to 35%, from 5% to 30%, from 5% to 25%, from 5% to 20%, from 10% to 70%, from 15% to 70%, from 20% to 70%, from 25% to 70%, from 30% to 70%, from 35% to 70%, from 40% to 70%, from 45% to 70%, from 50% to 70%, from 55% to 70%, from 10% to 65%, from 15% to 60%, from 20% to 55%, from 25% to 50%, or any combinations of these ranges. Without being bound by any particular theory, it is believed that a porosity of less than 5% may not provide an adequate stress buffer to limit fractures in the glass-based substrate 110. It is also believed that a porosity of greater than 70% may cause the first polymer layer 120 and the second polymer layer 130 to be structurally unsound.

In some embodiments, the pores in the first polymer layer 120 and the second polymer layer 130 may have a pore size that is from 0.1 μm to 10 μm. As described herein, the pore size may be an average pore size that is measured by BET method, mercury intrusion, or electron microscopy. The pore size may be controlled by using a sacrificial template or porogens. In some embodiments, the pores in the first polymer layer 120 and the second polymer layer 130 may have a pore size that is from 0.5 μm to 10 μm, from 1 μm to 10 μm, from 2 μm to 10 μm, from 3 μm to 10 μm, from 4 μm to 10 μm, from 5 μm to 10 μm, from 6 μm to 10 μm, from 7 μm to 10 μm, from 8 μm to 10 μm, from 9 μm to 10 μm, from 1 μm to 9 μm, from 1 μm to 8 μm, from 1 μm to 7 μm, from 1 μm to 6 μm, from 1 μm to 5 μm, from 1 μm to 4 μm, from 1 μm to 3 μm, from 1 μm to 2 μm, or any combinations of these ranges. Without being bound by any particular theory, it is believed that a pore size of less than 0.1 μm may not be large enough to provide an adequate stress buffer to limit fractures in the glass-based substrate 110. It is also believed that a pore size of greater than 10 μm may cause the first polymer layer 120 and the second polymer layer 130 to be structurally unsound.

As stated herein, in one or more embodiments, the at least one RDL 140 may comprise the metal material 142 and the dielectric material 144. The metal material 142 and the dielectric material 144 may be integrated, such that the two materials are joined in an intertwined manner. The metal material 142 and the dielectric material 144 may be integrated during the formation process of the microelectronic article 100. As a non-limiting example, the RDL 140 may be formed by disposing the metal material 142 on the first polymer layer 120. The metal material 142 may then be chemically etched or patterned resulting in gaps with no metal material 142 present. The dielectric material 144 may be disposed on the patterned metal material 142 such that the dielectric material 144 fills the gaps in the metal material 142 while simultaneously forming on top of the patterned metal material 142. The same process may be employed on the dielectric material 144 of chemical etching or patterning creating gaps in the dielectric material 144, disposing metal material 142 to fill the gaps in the dielectric material 144 with the formation of metal material 142 disposed on the newly formed dielectric material 144. The process may be subsequently repeated with the metal material 142 and the dielectric material 144 to build up the desired thickness and makeup of the RDL 140. This process may create the “integrated” RDL 140 wherein the metal material 142 and the dielectric material 144 are joined in an intertwined, or interlocked, manner, as shown in FIG. 2. Additionally, as shown in FIG. 2, in some embodiments, the RDLs 140 may be symmetric with respect to the mid-plane 118 of the glass-based substrate 110, wherein each RDL 140 may comprise the metal material 142 and the dielectric material 144 in the same disposal order and/or same etched pattern reflected across the mid-plane 118. In other embodiments (not shown), the RDLs 140 may not be symmetric with respect to the mid-plane 118.

In one or more embodiments, the at least one redistribution layer 140 may have a thickness of at least 500 nm. For example, the at least one redistribution layer 140 may have a thickness of at least 520 nm, at least 540 nm, at least 560 nm, at least 580 nm, at least 600 nm, at least 560 nm, at least 570 nm, at least 580 nm, at least 590 nm, at least 600 nm.

Referring now to FIG. 3, a microelectronic article prestructure 200 according to one or more embodiments described herein is depicted. Embodiments of the microelectronic article pre-structure 200 depicted in FIG. 3 comprise a glass-based substrate 110 comprising a first surface 112 and a second surface 114. At least one polymer layer 120, 130 is disposed on the first surface 112, the second surface 114, or both. FIG. 3 depicts an embodiment where a first polymer layer is disposed on the first surface 112 and a second polymer layer is disposed on the second surface 114. However, it should be understood that the microelectronic article pre-structure 100 may comprise only one polymer layer disposed on a surface of the glass-based substrate 110. The at least one polymer layer 120, 130 comprises pores and has a porosity of from 5% to 70% and a Young's modulus of greater than 1 GPa, as is described herein.

Still referring to FIG. 3, in some embodiments, the microelectronic article pre-structure 200 may not include a redistribution layer. The porous polymer layers 120, 130 may be disposed on the glass-based substrate 110 to create a stress buffer layer, as described herein. In some embodiments, the microelectronic article pre-structure 200, having only the polymer layers 120, 130 on the glass-based substrate 110, may be sent to downstream processes to form redistribution layers or other modifications that may impart stresses onto the microelectronic article pre-structure 200. Thus, it should be understood that the at least one polymer layer 120, 130 may act as a stress-buffer layer for any downstream processes, including formation of at least one redistribution layer. In some embodiments, the microelectronic article pre-structure 200 may include a through glass vias (not shown in FIG. 3), which may or may not be filled with a metal material 142. In some embodiments, the microelectronic article pre-structure 200 may further comprise at least one redistribution layer (not shown in FIG. 3) disposed on the at least one polymer layer 120, 130. The at least one redistribution layer may comprise a metal material and a dielectric material, as described herein. A microelectronic article pre-structure 200 that comprises at least one redistribution layer may be considered a microelectronic article, as known to those skilled in the art.

Now referring to FIG. 4, a microelectronic article 100 according to one or more embodiments described herein is depicted. Embodiments of the microelectronic article 100 depicted in FIG. 4 comprise a glass-based substrate 110 comprising a first surface 112 and a second surface 114 and a redistribution layer 140 disposed on at least one of the first surface 112, the second surface 114, or both. The redistribution layer(s) 140 may comprise a metal material 142 and a dielectric material 144, as described herein.

Still referring to FIG. 4, in one or more embodiments, the dielectric material 144 may comprise pores. The pores of the dielectric material 144 may be similar or even identical to the pores described hereinabove with respect to FIG. 2. The pores of the dielectric material 144 may have a pore size that is from 0.1 μm to 10 μm or any of the subranges described hereinabove with respect to FIG. 2. In some embodiments, the composition of the first polymer layer 120 and the second polymer layer 130, as depicted in FIG. 2, is identical to the composition of the porous dielectric material 144, as depicted in FIG. 4. The porous dielectric material 144 may act as a stress buffer to mitigate the stresses applied to the glass-based substrate 110 by the at least one redistribution layer 140. In some embodiments, although not shown, the dielectric material 144 in FIG. 2 may also comprise pores to act as an additional stress buffer.

Referring now to FIGS. 2-4, in some embodiments, one or more of the first polymer layer 120, the second polymer layer 130, and the dielectric material 144 may comprise photo-patternable polyimide, polybenzoxazoles, polyolefin, polystyrene, benzocyclobutene, ring-opened norbornen type polymers, or combinations thereof. As a non-limiting example, the first polymer layer 120 and the second polymer layer 130 may comprise photo-patternable polyimide and the dielectric material 144 may comprise polyolefin. In other embodiments, the first polymer layer 120, the second polymer layer 130, and the dielectric material 144 may comprise photo-patternable polyimide.

In some embodiments, one or more of the first polymer layer 120, the second polymer layer 130, and the dielectric material 144 may have a Young's modulus that is greater than 1 GPa. For example, in some embodiments, the first polymer layer 120 and the second polymer layer 130 may have a Young's modulus that is greater than 1.5 GPa, greater than 2 GPa, greater than 2.5 GPa, greater than 3 GPa, greater than 3.5 GPa, greater than 4 GPa, greater than 4.5 GPa, greater than 5 GPa, greater than 5.5 GPa, greater than 6 GPa, greater than 6.5 GPa, greater than 7 GPa, greater than 7.5 GPa, greater than 8 GPa, greater than 8.5 GPa, greater than 9 GPa, or even greater than 9.5 GPa. In some embodiments, one or more of the first polymer layer 120, the second polymer layer 130, and the dielectric material 144 may have a Young's modulus that is from 1 GPa to 10 GPa, such as from 1 GPa to 9 GPa, from 1 GPa to 8 GPa, from 1 GPa to 7 GPa, from 1 GPa to 6 GPa, from 1 GPa to 5 GPa, from 1 GPa to 4 GPa, from 1 GPa to 3 GPa, from 1 GPa to 2 GPa, from 2 GPa to 10 GPa, from 3 GPa to 10 GPa, from 4 GPa to 10 GPa, from 5 GPa to 10 GPa, from 6 GPa to 10 GPa, from 7 GPa to 10 GPa, from 8 GPa to 10 GPa, from 9 GPa to 10 GPa, from 2 GPa to 9 GPa, from 3 GPa to 8 GPa, from 4 GPa to 7 GPa, from 5 GPa to 6 GPa, or any combinations of these ranges. Without being bound by any particular theory, the first polymer layer 120, the second polymer layer 130, or both with a Young's modulus that is greater than 1 GPa and less than 10 GPa may act as suitable buffer layers between the glass-based substrate 110 and the RDLs 140. The dielectric material 144 with a Young's modulus greater than 1 GPa may also act as additional buffer layers in the microelectronic article 100. It is believed that a Young's modulus of less than 1 GPa would cause reliability and structural issues due to the extreme porosity. Further, a Young's modulus of greater than 10 GPa would not act as a suitable buffer to achieve stress reduction.

In some embodiments, one or more of the first polymer layer 120, the second polymer layer 130, and the dielectric material 144 may have a coefficient of thermal expansion (CTE) that is greater than or equal to 3×10⁻⁶/° C. over a temperature range of −100° C. to 450° C. For example, in some embodiments, one or more of the first polymer layer, the second polymer layer, and the dielectric material may have a CTE that is greater than or equal to 4×10⁻⁶/° C., greater than or equal to 5×10⁻⁶/° C., greater than or equal to 6×10⁻⁶, greater than or equal to 7×10⁻⁶/° C., greater than or equal to 8×10⁻⁶/° C., greater than or equal to 9×10⁻⁶/° C., greater than or equal to 10×10⁻⁶/° C., greater than or equal to 11×10⁻⁶/° C., greater than or equal to 12×10⁻⁶/° C., greater than or equal to 13×10⁻⁶/° C., greater than or equal to 14×10⁻⁶/° C., or even greater than or equal to 15×10⁻⁶/° C. Without being bound by any particular theory, it is believed that, in some embodiments, a CTE of greater than 3×10⁻⁶/° C. may lower the risk of lateral fractures in the glass-based substrate 110. However, it is also believed that incorporating pores, as described herein, may improve the buffer effect of the polymer with any CTE.

In some embodiments, one or more of the first polymer layer 120, the second polymer layer 130, and the dielectric material 144 may comprise an adhesion promoter. For example, one or more of the first polymer layer 120, the second polymer layer 130, and the dielectric material 144 may comprise silane. In some embodiments, the one or more of the first polymer layer 120, the second polymer layer 130, and the dielectric material 144 may comprise alkyltrialkoxysilanes, methyltriethoxysilane, methyltrimethoxysilane, octyltrimethoxysilane, octadecyltrimethoxysilane, polyalkoxysiloxane compounds, aminoalkyltrialkoxysilane, γ-aminopropyltriethoxysilane, -aminopropyltrimethoxysilane, N-β-(aminoethyl)-γ-aminopropyltrimethoxysilane, γ-ureido propyltriethoxysilane, N-(2-aminoethyl)-3-aminopropyltrimethoxysilane, 13-(3,4-epoxycyclohexyl)ethyltrimethoxysilane. The adhesion promoter may increase the adhesion of one or more of the first polymer layer 120, the second polymer layer 130, and the dielectric material 144 to the glass-based substrate 110 and/or to the metal material 142. Additionally, the presence of adhesion promotors may create an anchor between the glass-based substrate 110 and the polymer layers 120, 130 by forming an Si—O—Si bond.

As stated herein, in one or more embodiments, the at least one RDL 140 may be disposed on the first polymer layer 120, the second polymer layer 140, or both. As shown in FIG. 2, in embodiments, the microelectronic article 100 may comprise a RDL 140 disposed on the first polymer layer 120 and a RDL 140 disposed on the second polymer layer 130. The at least one RDL 140 may comprise a metal material 142 and a dielectric material 144. In some embodiments, the RDLs 140 may comprise only the metal material 142, such as one layer of the metal material 142. In some embodiments, the metal material 142 may be copper, aluminum, silver, tin, aluminum-copper, gold, titanium, titanium-tungsten, tantalum, tantalum-nitride chromium, nickel, or combinations thereof.

Referring to FIGS. 2 and 4, in some embodiments, the microelectronic article 100 may further comprise a through glass via 150 extending through the glass-based substrate 110 from the first surface 112 to the second surface 114. In some embodiments, such as the embodiment depicted in FIGS. 2 and 4, the through glass via 150 comprises the metal material 142. The metal material 142 may be the same metal material 142 of the RDL 140. The metal material 142 may extend through the microelectronic article 100, such that the metal material 142 extends through the glass-based substrate 110, the first polymer layer 120, the second polymer layer 130, and the RDL 140. The metal material 142 may serve as an electric interconnect through the microelectronic article 100.

Referring to FIG. 2, in some embodiments, the through glass via 150 may be formed by chemical etching or laser damaging the glass-based substrate 110. After cleaning the glass-based substrate 110, the first polymer layer 120 and the second polymer layer 130 may be overlaid on the glass-based substrate 110. A channel extending the through glass via 150 may then be formed in the first polymer layer 120 and the second polymer layer 130 by chemical etching and/or laser damage. In some embodiments, the through glass via 150 may comprise the metal material 142. As used herein, a “metallized through glass via” may refer to a through glass via that comprises the metal material 142. In some embodiments, metal material 142 may be introduced into the through glass via 150. In embodiments, the metal material 142 may completely fill the through glass via 150. In one or more embodiments, the metal material 142 may coat the surfaces of the through glass via 150. The metallized through glass via 150 may serve as an electric connection through the microelectronic article 100.

In some embodiments, the microelectronic article 100 may comprise an electric connection on an exterior of the microelectronic article 100. The electric connection may comprise the metal material 142. For example, the metal material 142 may be wrapped around an exterior of the microelectronic article 100. Without limitation, the metal material 142 may comprise a wire, an electrode, or other electrically conductive materials, such as the metal materials previously disclosed herein. In such embodiments, the metal material 142 may serve as an electric connection on the exterior of the microelectronic article 100.

According to one or more embodiments, the microelectronic article 100 may comprise a glass-based substrate 110 comprising a first surface 112 and a second surface 114, a first polymer layer 120 disposed on the first surface 112, a second polymer layer 130 disposed on the second surface 114, at least one RDL 140 disposed on the first polymer layer 120, the second polymer layer 130, or both, and a metallized through glass via 150 extending from the first surface 112 of the glass-based substrate 110 to the second surface 114 of the glass-based substrate 110. In one or more embodiments, the at least one RDL 140 may comprise a metal material 142 and a dielectric material 144.

In some embodiments, the first polymer layer 120 and the second polymer layer 130 may be non-porous. The first polymer layer 120 and the second polymer layer 130 may comprise one or more additives. In some embodiments, the one or more additives may be organic materials. The organic additives may be hollow structures that allows them to be compressible. For example, the one or more additives may comprise hollow polyethylene, polystyrene and poly(methyl methacrylate), cage-like structures, such as hydrogen silsesquioxane (HSQ), methyl silsesquioxane (MSQ), or combinations thereof. Additionally, the one or more additives may also be inorganic materials, such as, in some embodiments, hollow silica beads. Without being bound by any particular theory, it is believed that the one or more additives may decrease the Young's modulus while also lowering or having a minimal effect on CTE of the first polymer layer 120 and the second polymer layer 130.

According to one or more embodiments, the elastic modulus of the organic additives may be less than or equal to the elastic modulus of polymer used in the first polymer layer 120, the second polymer layer 130, or both, therefore lowering the effective elastic modulus of the first polymer layer 120, the second polymer layer 130, or both, with minimal impact on the effective CTE. By lowering the effective elastic modulus, the polymer layers 120, 130 may act as better buffer layers between the glass-based substrate 110 and the RDLs 140. Additionally, hollow/shell inorganic additives (e.g., SiO₂), may have CTE values less than the polymer used in the first polymer layer 120, the second polymer layer 130, or both, and a minimal change in the effective elastic modulus of the first polymer layer 120, the second polymer layer 130, or both. Lowering the effective CTE of the polymer layers 120, 130 may lead to reduced stresses in the glass-based substrate 110. As such, in some embodiments, a combination of hollow organic and inorganic additives may enable a simultaneous decrease in the CTE and elastic modulus of the first polymer layer 120, the second polymer layer 130, or both.

The additives may allow the polymer layers to act as stress buffer layers. In some embodiments, the first polymer layer 120 and the second polymer layer 130 may comprise the one or more additives and pores. In such embodiments, the pores and the additives may be useful to lower the stresses applied to the glass-based substrate 110 from the RDLs 140.

Referring to FIGS. 2 and 3, in some embodiments, the first polymer layer 120 and the second polymer layer 130 may have a decomposition temperature of greater than or equal to 200° C. For example, in some embodiments, the first polymer layer 120 and the second polymer layer 130 may have a decomposition temperature of greater than or equal to 210° C., greater than or equal to 220° C., greater than or equal to 230° C., greater than or equal to 240° C., greater than or equal to 250° C., greater than or equal to 260° C., greater than or equal to 270° C., greater than or equal to 280° C., greater than or equal to 290° C., greater than or equal to 300° C., greater than or equal to 310° C., greater than or equal to 320° C., greater than or equal to 330° C., greater than or equal to 340° C., or even greater than or equal to 350° C.

In some embodiments, the first polymer layer 120 and the second polymer layer 130 may have a coefficient of thermal expansion (CTE) of greater than or equal to 3×10⁻⁶/° C. For example, in some embodiments, one or more of the first polymer layer, the second polymer layer, and the dielectric material may have a CTE of greater than or equal to 4×10⁻⁶/° C., greater than or equal to 5×10⁻⁶/° C., greater than or equal to 6×10⁻⁶/° C., greater than or equal to 7×10⁻⁶/° C., greater than or equal to 8×10⁻⁶/° C., greater than or equal to 9×10⁻⁶/° C., greater than or equal to 10×10⁻⁶/° C., greater than or equal to 11×10⁻⁶/° C., greater than or equal to 12×10⁻⁶/° C., greater than or equal to 13×10⁻⁶/° C., greater than or equal to 14×10⁻⁶/° C., or even greater than or equal to 15×10⁻⁶/° C.

Now, processes for forming the porous polymer layers are described. The processes described herein may apply to embodiments in which the dielectric material 144 is porous. It should be understood that the processes of forming the porous polymer layers described are non-limiting and other processes for forming porous polymer layers are contemplated.

In some embodiments, the first polymer layer 120, the second polymer layer 130, or both may comprise polyimide. Without being bound by any particular theory, polyimide possesses excellent thermal, mechanical, and electrical stability and electrical insulation properties. Polyimide also has good adhesion to glass-based substrates and metal materials such as copper.

In some embodiments, a polyimide-containing organic solution may be formed by creating a volatile microemulsion of polyimide and water. The polyimide-containing organic solution may be disposed on the glass-based substrate 110. After evaporation of the water, a porous polyimide layer may be formed.

In other embodiments, silica microspheres may be added to polyamic acid (PAA) in dimethyl formamide (DMF) to form a solution. The solution may be disposed on the glass-based substrate 110 and undergo imidization to create a polyimide/SiO₂ composite film. The composite film may be etched in hydrofluoric acid solution or non-hydrofluoric acid solution which removes the silica microspheres from the polyimide, thus forming a porous polyimide layer.

In other embodiments, porous polyhedral oligomeric silsesquioxane (POSS) may be used as a first polymer layer 120, a second polymer layer 130, or both. Without being bound by any particular theory, POSS comprises a 3-D, cage-like structure and has an inorganic framework comprising Si—O structures. Compared with other porous materials, POSS has active functional groups to create chemical bonds and homogenous porous structures with a polymer polyimide matrix. In addition, POSS has good adhesion to glass and glass-based substrates. The porosity of POSS may be finetuned to modify POSS to adhere to metal materials, such as copper, as well. In some embodiments, the polymer layers 120, 130 may be formed by disposing POSS onto the glass-based substrate 110.

In other embodiments, porous sol-gel films may be used as the first polymer layer 120, the second polymer layer 130, or both. The sol-gel films may have excellent adhesion to glass and glass-based substrates, as well as metal materials. In some embodiments, silicon alkoxide (TEOS) may be hydrolyzed and condensed in water under the action of a base catalyst (NH₄OH) without ethanol. Acetic acid may be added to the SiO₂ gel solution to slow down the speed of condensation and delay the growth of SiO₂ gel particles. Polyvinyl alcohol (PVA) may be added to the solution to coat the SiO₂ gel particles in order to obtain a stable solution and to restrict the growth of the SiO₂ gel particles. The gel-solution may be disposed on the glass-based substrate 110. This process may form polymer layers 120, 130 by spin coating after annealing at a temperature of from 500° C. to 600° C., such as 550° C., and for a duration of from 15 minutes (min) to 60 min, such as 30 min.

The present disclosure includes numerous aspects, including aspects 1-20 described herein.

A first aspect of the present disclosure is directed to a microelectronic article comprising: a glass-based substrate comprising a first surface and a second surface; a first polymer layer disposed on the first surface; a second polymer layer disposed on the second surface; at least one redistribution layer disposed on the first polymer layer, the second polymer layer, or both; a metallized through glass via extending from the first surface to the second surface, wherein: the first polymer layer and the second polymer layer comprise pores and have a porosity of from 5% to 70% and a Young's modulus of greater than 1 GPa; and the at least one redistribution layer comprises a metal material and a dielectric material.

A second aspect of the present disclosure may include the first aspect, wherein the first polymer layer and the second polymer layer comprise hollow polyethylene, polystyrene, poly(methyl methacrylate), hydrogen silsesquioxane, methyl silsesquioxane, hollow silica beads, or combinations thereof.

A third aspect of the present disclosure may include any one of the first or second aspects, wherein one or more of the first polymer layer, the second polymer layer, and the dielectric material has a coefficient of thermal expansion of greater than or equal to 3×10⁻⁶/° C.

A fourth aspect of the present disclosure is directed to a microelectronic article comprising: a glass-based substrate comprising a first surface and a second surface; at least one redistribution layer disposed on the first surface, the second surface, or both; a metallized through glass via extending from the first surface to the second surface, wherein: the at least one redistribution layer comprises a dielectric material and a metal material; and the dielectric material comprises pores and has a porosity of from 5% to 70% and a Young's modulus of greater than 1 GPa.

A fifth aspect of the present disclosure may include any one of the first through fourth aspects, wherein the pores have an average pore size of from 0.1 μm to 10 μm.

A sixth aspect of the present disclosure is directed to a microelectronic article comprising: a glass-based substrate comprising a first surface and a second surface; a first polymer layer disposed on the first surface; a second polymer layer disposed on the second surface; at least one redistribution layer disposed on the first polymer layer, the second polymer layer, or both; a metallized through glass via extending from the first surface to the second surface, wherein: the first polymer layer and the second polymer layer have a Young's modulus greater than 1 GPa, a decomposition temperature of greater than or equal to 200° C., and a coefficient of thermal expansion of greater than or equal to 3×10⁻⁶/° C.; and the at least one redistribution layer comprises a metal material and a dielectric material.

A seventh aspect of the present disclosure may include the sixth aspect, wherein the first polymer layer and the second polymer layer have a decomposition temperature of greater than or equal to 200° C. and a coefficient of thermal expansion of greater than or equal to 3×10⁻⁶/° C.

An eighth aspect of the present disclosure may include any one of the first through seventh aspects, further comprising an electric connection extending through the microelectronic article, wherein the electric connection comprises the metallized through glass via.

A ninth aspect of the present disclosure may include any one of the first through eighth aspects, further comprising an electric connection on the exterior of the microelectronic article.

A tenth aspect of the present disclosure may include the ninth aspect, wherein the electric connection comprises the metal material.

An eleventh aspect of the present disclosure may include any one of the sixth through tenth aspects, wherein the first polymer layer, the second polymer layer, or both comprise pores.

A twelfth aspect of the present disclosure may include any one of the first through eleventh aspects, wherein the dielectric material comprises photo-patternable polyimide, polybenzoxazoles, polyolefin, polystyrene, benzocyclobutene, ring-opened norbornen type polymers, or combinations thereof.

A thirteenth aspect of the present disclosure may include any one of the first through twelfth aspects, wherein one or more of the first polymer layer, the second polymer layer, and the dielectric material comprises an adhesion promoter.

A fourteenth aspect of the present disclosure may include any one of the first through thirteenth aspects, wherein the metal material comprises copper, aluminum, silver, tin, aluminum-copper, gold, titanium, titanium-tungsten, tantalum, tantalum-nitrogen, chromium, nickel, or combinations thereof.

A fifteenth aspect of the present disclosure may include any one of the first through fourteenth aspects, wherein the glass-based substrate has a coefficient of thermal expansion of from 0.5×10⁻⁶/° C. to 13×10⁻⁶/° C.

A sixteenth aspect of the present disclosure may include any one of the first through fifteenth aspects, wherein the glass-based substrate has a Young's modulus of from 50 GPa to 200 GPa.

A seventeenth aspect of the present disclosure may include any one of the first through sixteenth aspects, wherein the metal material and the dielectric material are integrated in the redistribution layer.

An eighteenth aspect of the present disclosure is directed to a microelectronic article pre-structure comprising: a glass-based substrate comprising a first surface and a second surface; at least one polymer layer disposed on the first surface, the second surface, or both; wherein: the at least one polymer layer comprise pores and has a porosity of from 5% to 70% and a Young's modulus of from 1 GPa to 10 GPa.

A nineteenth aspect of the present disclosure may include the eighteenth aspect, further comprising at least one redistribution layer disposed on the at least one polymer layer, wherein the at least one redistribution layer comprises a metal material and a dielectric material.

A twentieth aspect of the present disclosure may include any one of the eighteenth or nineteenth aspects, wherein a first polymer layer is disposed on the first surface and a second polymer layer is disposed on the second surface.

A twenty-first aspect of the present disclosure may include any one of the eighteenth through twentieth aspects, wherein the pores have an average pore size of from 0.1 μm to 10 μm.

### EXAMPLES

The various embodiments of the present disclosure will be further clarified by the following examples. The examples are illustrative in nature and should not be understood to limit the subject matter of the present disclosure.

### Example I: Finite Element Modeling Study

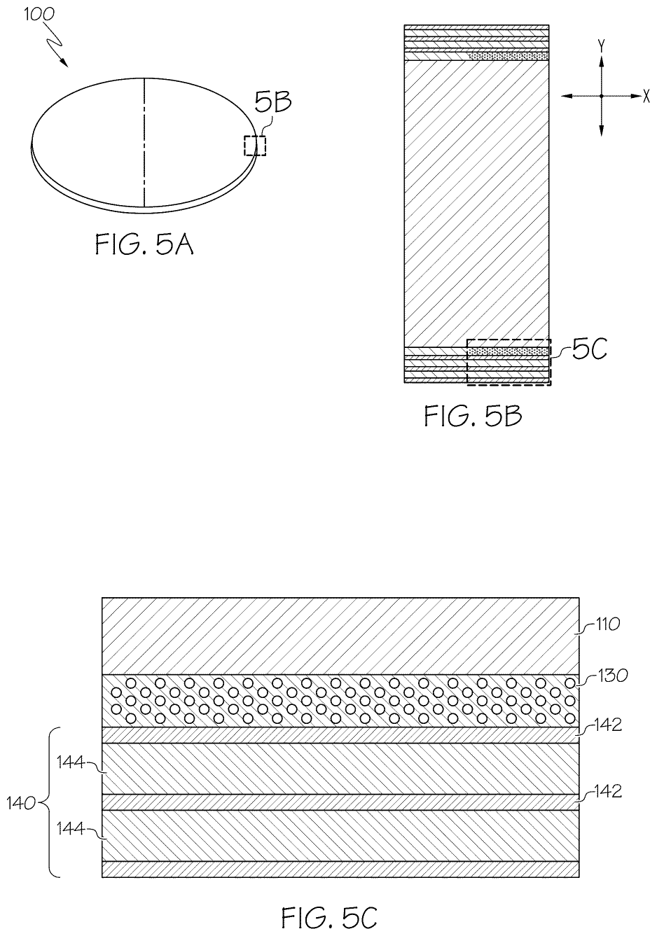

A 2D axisymmetric finite element model, as shown in FIGS. 5A-5C, was created in a commercial finite element software (ANSYS Mechanical 2023R1). FIG. 5A depicts a microelectronic article, as described in embodiments herein, with a cylindrical disk geometry. The cylindrical disk geometry was used to evaluate stresses resulting in the lateral fractures of the glass-based substrate. FIG. 5B depicts a cross-sectional side view of the edge of the microelectronic article model of FIG. 5A with both surfaces of the glass-based substrate symmetrically coated with polymer layers and metal layers as described further herein. FIG. 5C depicts a magnified view of a corner of the cross-sectional edge side view of FIG. 5B. As shown in FIG. 5C, the microelectronic article model has a redistribution layer 140 with three layers of the metal material 142 and two layers of the dielectric material 144, a polymer layer 130 with pores, and a glass-based substrate 110. In the simulated model, the glass-based substrate 110 was coated with the metal material 142, the dielectric material 144, and the polymer layer 130 in different sequences depending on the investigated example. It should be understood that FIGS. 5A-5C depict a microelectronic article with a porous polymer layer, but two other examples, as described below, were also evaluated.

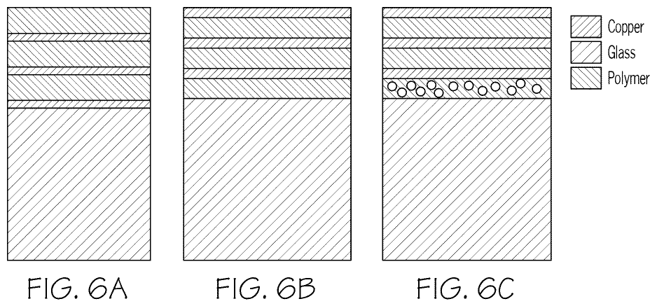

Referring now to FIGS. 6A-6C, schematic illustrations of cross-sectional side views of the edges of microelectronic articles are depicted, as described in embodiments herein. It should be understood that FIGS. 6A-6C depict only a portion of the microelectronic article studied. Three examples were modeled with different first layers in contact with the glass. In Comparative Example A, the first layer in contact with the glass is copper, as shown in FIG. 6A. In Example 1, the first layer in contact with the glass is non-porous polymer, as shown in FIG. 6B. In Example 2, the first layer in contact with the glass is porous polymer, as shown in FIG. 6C. In these models, the polymer used for the dielectric material layers and the polymer layer are the same polymer. The polymer layers (porous and non-porous) had a thickness of 15 μm. The copper layers had a thickness of 5 μm. The glass-based substrate had a thickness of 500 μm. The properties of the materials used are shown in Table 1.

TABLE 1

| | CTE | Young's modulus | Poisson's |
|---|---|---|---|
| Material | (/° C.) | (GPa) | Ratio |
| Glass | 3.8e−6 | 73 | 0.20 |
| Copper | 17.2e−6 | 117.7 | 0.34 |
| Polymer | 36e−6 | 5 | 0.314 |

FIG. 6A depicts a portion of the microelectronic model of Comparative Example A. Comparative Example A was formed by the following process. In the first coating step, layers of copper were disposed on the first and second surfaces of the glass. In the second step, layers of the polymer material were disposed on the copper layers. Subsequently, the first step and the second step were repeated until there were three copper layers and three polymer layers on each surface of the glass.

FIG. 6B depicts a portion of the microelectronic article model of Example 1. Example 1 was formed by the following process: In the first coating step, a layer of non-porous polymer was disposed on the first and second surfaces of the glass. In the second step, a layer of copper was disposed on the layers of non-porous polymer. In the third step, layers of the non-porous polymer were disposed on both previously coated copper layers. Subsequently, steps two and three were repeated until there were three copper layers and three non-porous polymer layers disposed on the glass.

FIG. 6C depicts a portion of the microelectronic article model of Example 2. Example 2 was formed by a process similar to Example 1, except in the first coating step, a layer of porous polymer was disposed on the first and second surfaces of the glass.

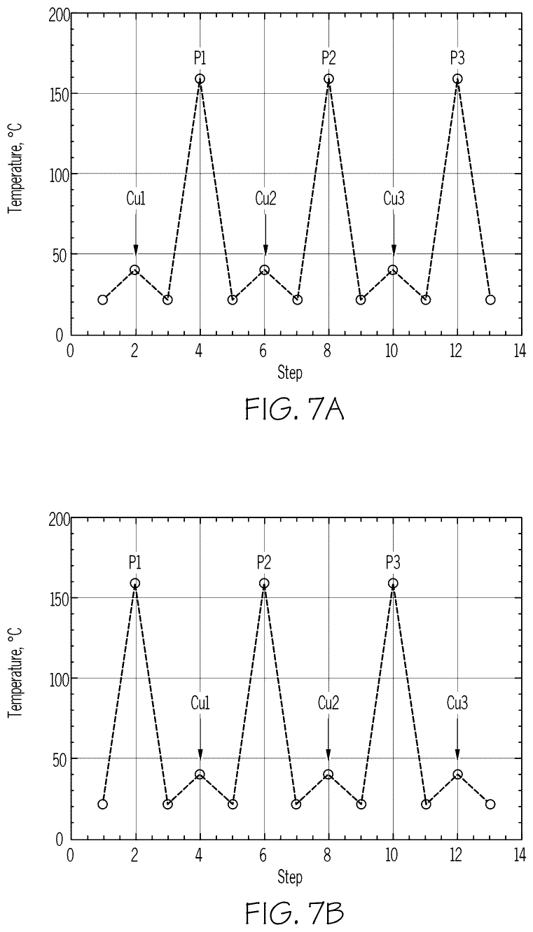

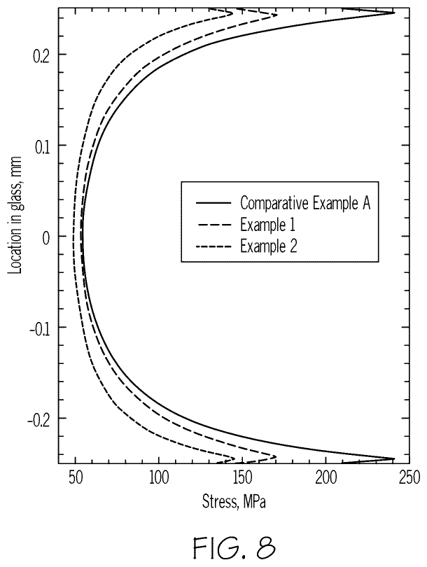

In the Finite Elemental Model study for all three examples, stress-free deposition temperatures of 180° C. and 160° C. were used for the metal material (copper) and the polymer, respectively. The “stress-free deposition temperature” refers to the temperature at which no residual stresses are present in the material (e.g., copper or polymer) when the material is disposed. Upon cooling from the corresponding temperatures, the evaluated stresses were due to CTE mismatch only. The applied temperature cycling profiles are depicted in FIGS. 7A and 7B. FIG. 7A depicts the applied temperature cycling profile of Comparative Example A with copper as the first layer in contact with the glass. FIG. 7B depicts the applied temperature cycling profile of Example 1 and Example 2 with the polymer as the first layer in contact with the glass. The deposition temperature of the polymer layers were assumed to be the zero-stress temperature of 160° C. The deposition temperature of the copper layers was initially assumed to be the zero-stress temperature of 40° C. Upon cooling from the copper deposition temperature to room temperature, the model assumed that the copper layers were subjected to annealing, which changed their zero-stress temperature to 180° C. The stresses were due to CTE mismatch and were evaluated at room temperature. The thermal strains in each layer (i.e., glass, copper, and polymer) were calculated as a product of CTE and the difference of the zero-stress temperature and room temperature.

Still referring to FIGS. 7A and 7B, thirteen steps were applied in the examples, with a “step” referring to an input temperature applied to the model. For each layer of copper, an input temperature of 40° C. was applied. The first layer of copper is labeled as Cu1, the second layer of copper is labeled as Cu2, and the third layer of copper is labeled as Cu3. For each layer of polymer, an input temperature of 160° C. was applied. The first layer of polymer is labeled as P1, the second layer of polymer is labeled as P2, and the third layer of polymer is labeled as P3. The first step, last step, and between each layer of copper and polymer, an input temperature of 20° C. was applied to the model to simulate room temperature.

For all three examples, the stresses responsible for lateral fractures in the glass gradually increased for each subsequent layer deposition step. The highest stress was observed once all the layers were deposited. Now referring to FIG. 8, a graph is depicted that shows the stress in the glass of each example after all layers were deposited. FIG. 8 shows the profile of the stress in the glass in the out-of-plane direction (i.e., the y-axis direction shown in FIG. 5B) with the mid-plane of the glass at 0 mm, the first surface of the glass at 0.25 mm and the second surface of the glass at −0.25 mm. Table 2 lists the stress at the first surface and the second surface of the glass for each example.

TABLE 2

| | | Stress at the first surface |
|---|---|---|
| | First layer in contact | and second surface |
| Example | with the glass | of the glass (MPa) |
| Comparative | Copper | 240 |
| Example A | | |
| Example 1 | Non-porous polymer | 170 |
| Example 2 | Porous polymer | 145 |

As shown in FIG. 8 and Table 2, Example 1 with non-porous polymer as the first layer shows a reduction in the stress at the surfaces of the glass compared to Comparative Example A with copper as the first layer. Example 1 has around a 30% reduction in stress compared to Comparative Example A with copper as the first layer. Further, Example 2 with porous polymer as the first layer has a much lower stress profile at the surfaces of the glass than Comparative Example A. Utilizing porous polymer as the first layer in contact with the glass leads to around a 40% reduction in the stresses at the surfaces of the glass compared to utilizing copper as the first layer. This demonstrates that the porous polymer layer described in embodiments herein acts as a stress buffer layer and lowers the stresses applied to the glass-based substrates, which may result in the decrease of lateral fractures. Additionally, using polymers described herein, even without pores, reduces the likelihood of the occurrence of lateral fractures in the glass of microelectronic articles described herein.

Having described the subject matter of the present disclosure in detail and by reference to specific embodiments, it is noted that the various details described in this disclosure should not be taken to imply that these details relate to elements that are essential components of the various embodiments described in this disclosure, even in cases where a particular element is illustrated in each of the drawings that accompany the present description. Rather, the appended claims should be taken as the sole representation of the breadth of the present disclosure and the corresponding scope of the various embodiments described in this disclosure. Further, it should be apparent to those skilled in the art that various modifications and variations can be made to the described embodiments without departing from the spirit and scope of the claimed subject matter. Thus, it is intended that the specification cover the modifications and variations of the various described embodiments provided such modification and variations come within the scope of the appended claims and their equivalents.

For the purposes of describing and defining the present inventive technology it is noted that the terms “substantially” and “about” are utilized herein to represent the inherent degree of uncertainty that may be attributed to any quantitative comparison, value, measurement, or other representation. The terms “substantially” and “about” are also utilized herein to represent the degree by which a quantitative representation may vary from a stated reference without resulting in a change in the basic function of the subject matter at issue.

It is noted that one or more of the following claims utilize the term “wherein” as a transitional phrase. For the purposes of defining the present invention, it is noted that this term is introduced in the claims as an open-ended transitional phrase that is used to introduce a recitation of a series of characteristics of the structure and should be interpreted in like manner as the more commonly used open-ended preamble term “comprising.”

As used herein, the singular forms “a”, “an”, and “the” include plural referents unless the context clearly dictates otherwise. Thus, for example, reference to “a” component includes aspects having two or more such components, unless the context clearly indicates otherwise.

As used herein, terms such as “first” and “second” are arbitrarily assigned and are merely intended to differentiate between two or more instances or components. It is to be understood that the words “first” and “second” serve no other purpose and are not part of the name or description of the component, nor do they necessarily define a relative location, position, or order of the component. Furthermore, it is to be understood that the mere use of the term “first” and “second” does not require that there be any “third” component, although that possibility is contemplated under the scope of the present disclosure.

What is claimed is:

1. A microelectronic article comprising:
a glass-based substrate comprising a first surface and a second surface;
a first polymer layer disposed on the first surface;
a second polymer layer disposed on the second surface;
at least one redistribution layer disposed on the first polymer layer, the second polymer layer, or both;
a metallized through glass via extending from the first surface to the second surface, wherein:
the first polymer layer and the second polymer layer comprise pores and have a porosity of from 5% to 70% and a Young's modulus of greater than 1 GPa; and
the at least one redistribution layer comprises a metal material and a dielectric material.

2. The microelectronic article of claim 1, wherein the first polymer layer and the second polymer layer comprise hollow polyethylene, polystyrene, poly(methyl methacrylate), hydrogen silsesquioxane, methyl silsesquioxane, hollow silica beads, or combinations thereof.

3. The microelectronic article of claim 1, wherein one or more of the first polymer layer, the second polymer layer, and the dielectric material has a coefficient of thermal expansion of greater than or equal to 3×10⁻⁶/° C. over a temperature range of from −100° C. to 450° C.

4. The microelectronic article of claim 1, wherein the pores have an average pore size of from 0.1 μm to 10 μm.

5. The microelectronic article of claim 1, wherein the first polymer layer and the second polymer layer have a decomposition temperature of greater than or equal to 200° C. and a coefficient of thermal expansion of greater than or equal to 3×10⁻⁶/° C.

6. The microelectronic article of claim 1, wherein the dielectric material comprises photo-patternable polyimide, polybenzoxazoles, polyolefin, polystyrene, benzocyclobutene, ring-opened norbornen type polymers, or combinations thereof.

7. The microelectronic article of claim 1, further comprising an electric connection extending through the microelectronic article, wherein the electric connection comprises the metallized through glass via.

8. The microelectronic article of claim 1, wherein one or more of the first polymer layer, the second polymer layer, and the dielectric material comprises an adhesion promoter.

9. The microelectronic article of claim 1, wherein the metal material comprises copper, aluminum, silver, tin, aluminum-copper, gold, titanium, titanium-tungsten, tantalum, tantalum-nitrogen, chromium, nickel, or combinations thereof.

10. The microelectronic article of claim 1, wherein the glass-based substrate has a coefficient of thermal expansion of from 0.5×10⁻⁶/° C. to 13×10⁻⁶/° C.

11. The microelectronic article of claim 1, wherein the glass-based substrate has a Young's modulus of from 50 GPa to 200 GPa.

12. A microelectronic article comprising:
a glass-based substrate comprising a first surface and a second surface;
a first polymer layer disposed on the first surface;
a second polymer layer disposed on the second surface;
at least one redistribution layer disposed on the first polymer layer, the second polymer layer, or both;
a metallized through glass via extending from the first surface to the second surface, wherein:
the first polymer layer and the second polymer layer have a Young's modulus of from 1 GPa to 10 GPa; and
the at least one redistribution layer comprises a metal material and a dielectric material.

13. The microelectronic article of claim 12, wherein the first polymer layer, the second polymer layer, or both comprise pores.

14. The microelectronic article of claim 12, wherein the dielectric material comprises photo-patternable polyimide, polybenzoxazoles, polyolefin, polystyrene, benzocyclobutene, ring-opened norbornen type polymers, or combinations thereof.

15. The microelectronic article of claim 12, wherein one or more of the first polymer layer, the second polymer layer, and the dielectric material comprises an adhesion promoter.

16. The microelectronic article of claim 12, wherein the first polymer layer and the second polymer layer have a decomposition temperature of greater than or equal to 200° C. and a coefficient of thermal expansion of greater than or equal to 3×10⁻⁶/° C.

17. A microelectronic article pre-structure comprising:
a glass-based substrate comprising a first surface and a second surface;
at least one polymer layer disposed on the first surface, the second surface, or both; wherein:
the at least one polymer layer comprise pores and has a porosity of from 5% to 70% and a Young's modulus of from 1 GPa to 10 GPa.

18. The microelectronic article pre-structure of claim 17, further comprising at least one redistribution layer disposed on the at least one polymer layer, wherein the at least one redistribution layer comprises a metal material and a dielectric material.

19. The microelectronic article pre-structure of claim 17, wherein a first polymer layer is disposed on the first surface and a second polymer layer is disposed on the second surface.

20. The microelectronic article pre-structure of claim 17, wherein the pores have an average pore size of from 0.1 μm to 10 μm.
